(19) United States
(12) Patent Application Publication
(10) Pub. No.: US 2025/0151425 A1
(43) Pub. Date: May 8, 2025

(54) APPARATUS AND METHOD

(71) Applicant: The University of Liverpool, Liverpool (GB)

(72) Inventors: Eva Vilella, Liverpool (GB); Matthew Franks, Zurich (CH); Chenfan Zhang, Liverpool (GB); Gianluigi Casse, Liverpool (GB)

(73) Assignee: The University of Liverpool, Liverpool (GB)

(21) Appl. No.: 18/835,886

(22) PCT Filed: Feb. 17, 2023
(86) PCT No.: PCT/GB2023/050362

§ 371 Date: Aug. 5, 2024

(30) Foreign Application Priority Data
Feb. 18, 2022 (GB) 2202198.4
Nov. 21, 2022 (GB) 2217395.9

(51) Int. Cl. H10F 39/18; G01T 1/24; H10F 39/00; H10F 77/20

(52) U.S. Cl. CPC H10F 39/1892; G01T 1/247; H10F 39/014; H10F 77/206

(57) ABSTRACT

A High Voltage Complementary Metal-Oxide-Semiconductor, HV-CMOS, sensor comprising a p-substrate having a topside and a backside;
wherein the topside comprises:
an array of mutually spaced apart pixel structures, including a first pixel structure, therein and/or thereon, wherein the first pixel structure comprises: a set of PMOS and NMOS transistors, including a first PMOS transistor having an n-well, SN, layer, and a first NMOS transistor having a p-well, SP, layer; a deep n-well, DN, structure having a DN layer; a p-type buried, BP, layer disposed to mutually isolate the SN layer and the DN layer; an n-type buried, BN, layer providing a SN/BN/DN stack; and a set of contacts, including a first contact, electrically coupled to the DN layer via the SN/BN/DN stack;
wherein the backside comprises:
a doped p+ layer therein and/or thereon; and
wherein the sensor comprises an HV bias contact electrically coupled only to the p+ layer, for backside biasing thereof.

### FIELD

The present invention relates to High Voltage Complementary Metal-Oxide-Semiconductor, HV-CMOS, sensors, for example for sensing charged particles.

### BACKGROUND TO THE INVENTION

The High Luminosity upgrade for the Large Hadron Collider (HL-LHC), which aims to be operational by the end of 2027, will increase the luminosity of the current LHC by a factor of 10, while the Future Circular Collider (FCC-hh) will have a further increased luminosity, for example. As a result, detectors (also known as sensors) in experiments around the beamline will be subject to much higher doses of radiation, of the order of 1 MeV neutron equivalent fluence of 1×10¹⁶ n_{eq} cm⁻², throughout their lifetime. Detectors will therefore be required to retain detection efficiency after extended use in these high radiation environments.

Fully monolithic High Voltage Complementary Metal-Oxide-Semiconductor (HV-CMOS) detectors (also known as sensors) are an extremely attractive option for these future experiments given that they remove the need for the expensive, time-consuming bump-bonding process required by the silicon pixel hybrids presently used by experiments at the LHC. In HV-CMOS detectors, the front-end electronics can be directly embedded in the sensor substrate, rather than being bump-bonded or glued to a separate sensor.

In addition, compared with conventional CMOS detectors, HV-CMOS devices may be biased to high voltages for fast charge collection by drift, ensuring the detector can quickly be ready for subsequent events, but also ensuring high radiation tolerances.

In large particle physics experiments, such as those at the Large Hadron Collider (LHC) at CERN, billions of collisions per second produce thousands of billions of particles. These particles pass through several layers of silicon detectors that surround the collision point. If a particle carries an electric charge, it will leave a trace in each layer of silicon. Similar to how conservationists use footprints on snowy paths to track and identify animals, physicists use traces in silicon detectors, like HV-CMOS, to reconstruct particle trajectories (known as particle tracking) and identify them. However, particle tracking is technologically very challenging. To simplify this problem, physicists need extremely fast and thin sensors with tiny sensing cells that measure accurate tracepoints while dissipating little power. Radiation tolerance and cost are also critical, as sensors have to survive many years of operation and typically cover several square meters.

The most common tracking sensor technology used today in physics experiments with high particle rates is based on a hybrid model. Hybrid detectors are named to reflect their composite nature; the sensing cell or pixel and the readout electronics are two separate entities (in two separate layers of silicon) and connected via tiny conductive bumps using flip-chip bump-bonding techniques.

Hybrid detectors offer the advantage of tailoring the design of the sensing device to tolerate very high integrated particle fluence. However, due to their multi-layer nature, hybrid detectors require substantial material thickness, limiting the accuracy with which particle trajectories can be measured. The bump-bonding process to connect the pixels to the readout electronics also imposes a minimum pixel size, making it impossible for these detectors to achieve the very fine point resolution necessary to resolve the many millions of particle trajectories expected at the highest rate future experiments. Moreover, bump-bonding is complex and comes with prohibitive costs. The approximate cost of instrumenting 1 m² with hybrid detectors costs £1M, and tracker detectors in future experiments will require many square meters.

CMOS sensors, more generally monolithic sensors, integrate the sensing element and readout electronics in a single layer of thin silicon, which removes the need for interconnection with solder bump technology. Conventional CMOS sensors, however, cannot achieve sufficient readout speed and radiation tolerance to be a viable option for the high-rate particle tracking required in most state-of-the-art experiments. Nonetheless, these detectors have been successfully employed in a subset of experiments, like the upgrade of the ALICE experiment at the LHC, where lower readout speeds and moderate radiation tolerance are acceptable.

HV-CMOS sensors integrate the best of hybrid and conventional CMOS sensors. They provide fast-timing capability and excellent radiation tolerance like hybrids, they are also thin, with very small sensing cells for good tracepoint resolution, and are more affordable like conventional CMOS sensors. HV-CMOS sensors are the strongest candidate technology to meet all the performance requirements for future experiments. There is now a wide consensus within the community that monolithic sensors will replace hybrid sensor technologies in next-generation physics experiments.

HV-CMOS is the only sensor technology to date that shows great potential in fulfilling all the requirements outlined above. There is no other sensor technology that currently has the same promise. Silicon sensors require a sensing cell, which generates a small electric signal when a charged particle traverses it, and readout electronics to amplify and record this electric signal. Generally, HV-CMOS sensors integrate the sensing cell (pixel) and advanced readout electronics in a single layer of silicon that is as thin as a human hair. At the same time, HV-CMOS sensors also provide good tracepoint resolution (a 2 cm×2 cm sensor chip contains about 50,000 pixels), fast-timing capability, excellent radiation tolerance, and affordable cost per area. HV-CMOS sensors are emerging as a prime candidate to measure charged particles in many future physics experiments due to all these significant advantages.

However, HV-CMOS sensors have been irradiated and tested for fluences of the order 1 MeV neutron equivalent fluences of 2×10¹⁵ n_{eq} cm⁻², one order of magnitude lower than that of hybrids and as required by the HL-LHC. Measurements of irradiated silicon devices show that radiation damage changes the effective doping concentration N_{eff} of silicon. Which, as a result for high resistivity silicon, decreases the maximum size of the sensitive depletion depth, thereby reducing the amount of charge collected by drift and decreasing the signal-to-noise ratio.

Hence, there is a need to improve HV-CMOS sensors, for example for sensing charged particles, such as during and/or after irradiating.

### SUMMARY OF THE INVENTION

It is one aim of the present invention, amongst others, to provide a HV-CMOS sensor which at least partially obviates or mitigates at least some of the disadvantages of the prior art, whether identified herein or elsewhere. For instance, it is an aim of embodiments of the invention to provide a HV-CMOS sensor having an enhanced irradiation tolerance, an increased longevity and/or an improved sensitivity. For instance, it is an aim of embodiments of the invention to provide a HV-CMOS sensor having a greater pixel density and/or a higher pixel resolution.

A first aspect provides a High Voltage Complementary Metal-Oxide-Semiconductor, HV-CMOS, sensor comprising a p-substrate having a topside and a backside;
wherein the topside comprises:
an array of mutually spaced apart pixel structures, including a first pixel structure, therein and/or thereon, wherein the first pixel structure comprises: a set of PMOS and NMOS transistors, including a first PMOS transistor having an n-well, SN, layer, and a first NMOS transistor having a p-well, SP, layer; a deep n-well, DN, structure having a DN layer; a p-type buried, BP, layer disposed to mutually isolate the SN layer and the DN layer; an n-type buried, BN, layer providing an SN/BN/DN stack; and a set of contacts, including a first contact, electrically coupled to the DN layer via the SN/BN/DN stack;
wherein the backside comprises:
a doped p+ layer therein and/or thereon; and
wherein the sensor comprises an HV bias contact electrically coupled only to the p+ layer, for backside biasing thereof.

A second aspect provides a method of sensing charged particles using a High Voltage Complementary Metal-Oxide-Semiconductor, HV-CMOS, sensor according to the first aspect, the method comprising:
applying a voltage to the set of contacts, including the first contact, electrically coupled to the DN layer via the SN/BN/DN stack of the first pixel structure;
backside biasing the sensor via the HV bias contact, electrically coupled only to the p+ layer; and
sensing the charged particles.

A third aspect provides a method of fabricating a High Voltage Complementary Metal-Oxide-Semiconductor, HV-CMOS, sensor, the method comprising:
obtaining a p-substrate having a topside and a backside;
providing a topside of the p-substrate, comprising forming an array of mutually spaced apart pixel structures, including a first pixel structure, therein and/or thereon, wherein the first pixel structure comprises: a set of PMOS and NMOS transistors, including a first PMOS transistor having an n-well, SN, and a first NMOS transistor having a p-well, SP, layer; a deep n-well, DN, structure having a DN layer; a p-type buried, BP, layer disposed to mutually isolate the SN layer and the DN layer; an n-type buried, BN, layer providing an SN/BN/DN stack; and a set of contacts, including a first contact, electrically coupled to the DN layer via the SN/BN/DN stack; providing a backside of the p-substrate, comprising doping the p-substrate, thereby providing a doped p+ layer therein and/or thereon; and
electrically coupling an HV bias contact only to the p+ layer, for backside biasing thereof.

### DETAILED DESCRIPTION OF THE INVENTION

According to the present invention there is provided a HV-CMOS sensor, as set forth in the appended claims. Also provided is a method of sensing charged particles using a HV-CMOS sensor and a method of fabricating a HV-CMOS sensor. Other features of the invention will be apparent from the dependent claims, and the description that follows.

### HV-CMOS Sensor

The first aspect provides a High Voltage Complementary Metal-Oxide-Semiconductor, HV-CMOS, sensor comprising a p-substrate having a topside and a backside;
wherein the topside comprises:
an array of mutually spaced apart pixel structures, including a first pixel structure, therein and/or thereon, wherein the first pixel structure comprises: a set of PMOS and NMOS transistors, including a first PMOS transistor having an n-well, SN, layer, and a first NMOS transistor having a p-well, SP, layer; a deep n-well, DN, structure having a DN layer; a p-type buried, BP, layer disposed to mutually isolate the SN layer and the DN layer; an n-type buried, BN, layer providing an SN/BN/DN stack; and a set of contacts, including a first contact, electrically coupled to the DN layer via the SN/BN/DN stack;
wherein the backside comprises:
a doped p+ layer therein and/or thereon; and
wherein the sensor comprises an HV bias contact electrically coupled only to the p+ layer, for backside biasing thereof.

In this way, the HV bias may be increased relatively compared with a conventional HV-CMOS, for example to compensate for loss of gain during a lifetime thereof due to irradiation damage, thereby enhancing irradiation tolerance, increasing longevity and/or improving sensitivity of the HV-CMOS sensor, since the HV bias contact is electrically coupled only to (i.e. exclusively to) the p+ layer, for backside biasing thereof. It should be understood that the HV-CMOS sensor does not comprise (i.e. does not include; excludes) HV bias contacts electrically coupled to the topside. In this way, the pixel structures and the HV bias contact are on opposed sides (i.e. the topside and the backside respectively) of the p-substrate. Particularly, since the set of HV bias contacts, including the first HV bias contact, is electrically coupled only to (i.e. exclusively to) the p+ layer, for backside biasing thereof, onset of breakdown occurs at relatively higher HV bias voltages (for example, about 1,000 V i.e. an order of magnitude higher) compared with conventional HV-CMOS sensors (typically less than 100 V), thereby enabling the HV bias to be relatively increased.

Particularly, the inventors have identified that onset of breakdown of conventional HV-CMOS sensors may be determined by the mutual relative spatial proximity of HV bias contacts and pixel structures in and/or on the topside of the p-substrate. In order to increase pixel density and/or pixel resolution of conventional HV-CMOS sensors, a spacing between HV bias contacts and pixel structures in and/or on the topside of the p-substrate may be reduced. However, the inventors have identified that such a reduction in this spacing limits the HV bias that may be applied without onset of breakdown. In this way, longevity of such conventional HV-CMOS sensors is compromised since the potential increase in HV bias to compensate for loss of gain during a lifetime thereof due to irradiation damage is relatively limited.

In contrast, the inventors have realised that by providing the pixel structures and the HV bias contact, on opposed sides (rather than on the same topside) of the p-substrate, a spacing (i.e. a through thickness spacing) between the set of HV bias contacts electrically coupled only to the backside p+ layer and the array of pixel structures in and/or on the topside of the p-substrate may be maximised and/or optimised, for example for a given thickness of the p-substrate, while pixel density and/or pixel resolution increased, since the spacing between HV bias contacts and pixel structures is substantially independent of pixel density and/or pixel resolution. That is, onset of breakdown is now limited by the relatively greater through thickness spacing (tending towards a thickness of the p-substrate) between the HV bias contact electrically coupled only to the backside p+ layer and the array of pixel structures in and/or on the topside of the p-substrate. In this way, a HV-CMOS sensor according to the first aspect additionally and/or alternatively may have a greater pixel density and/or a higher pixel resolution while having a relatively higher HV bias breakdown voltage.

p-Substrate

The HV-CMOS sensor comprises the p-substrate having the topside and the backside. It should be understood that the topside and the backside are mutually opposed i.e. reversed sides of the p-substrate. Typically, the p-substrate comprises and/or is B-doped Si, for example having a resistivity of 1.9 kΩ·cm (about 7E12 at/cm³), Other suitable p-substrates are known, for example having a resistivity of a few kΩ·cm. It should be understood that while the HV-CMOS sensor as described with respect to the p-substrate, analogous HV-CMOS sensor may be fabricated using an n-substrate.

In one example, the p-substrate has a thickness in a range from 25 μm to 500 μm, preferably in a range from 50 μm to 300 μm. In this way, a through thickness spacing (tending towards a thickness of the p-substrate) between the HV bias contact electrically coupled only to the p+ layer and the array of pixel structures in and/or on the topside of the p-substrate may be increased, maximised and/or optimised, notwithstanding a desire to reduce a thickness of the p-substrate. Generally, relatively thicker sensors result in more scattering. Scattering deviates the trajectory of the particles, so it becomes more difficult to reconstruct their tracks. This is particularly important when the particles that need to be measured are very light.

### Topside

The topside comprises the array of mutually spaced apart pixel structures, including the first pixel structure, therein and/or thereon. Typically, HV-CMOS sensors comprise arrays of mutually spaced apart pixel structures, for example arranged in channels or rows and columns, for readout thereof, as understood by the skilled person. Particularly, as with conventional CMOS sensors, HV-CMOS sensors integrate the sensing elements (i.e. pixel structures) and readout electronics in a single layer of thin Czochralski silicon, which removes the need for interconnection with solder bump technology of hybrid sensors.

In one example, the array of mutually spaced apart pixel structures includes N mutually spaced apart pixel structures, wherein N is a natural number greater than 2, for example 3, 4, 5, 6, 7, 8, 9, 10, 20, 30, 40, 50, 60, 70, 80, 90, 100, 200, 500, 1,000 or more, for example 10,000, 20,000, 50,000, 100,000, 200,000, 500,000, 1,000,000, 2,000,000 or 5,000,000.

In one example, the array of mutually spaced apart pixel structures includes a second pixel structure and wherein the respective first contacts of the first pixel structure and the second pixel structure are mutually spaced apart by a spacing in a range from 1 μm to 20 μm, preferably in a range from 3 μm to 18 μm, more preferably in a range from 5 μm to 15 μm. It should be understood that the first pixel structure and the second pixel structure are mutually adjacent. In this way, the spacing between the mutually spaced apart first pixel structure and second pixel structure is reduced, thereby providing a greater pixel density (i.e. pixel number density per unit area) since gaps (i.e. the spacing) reduce, thereby increasing an effective area of the HV-CMOS sensor.

### Pixel Structure

The first pixel structure comprises: the set of PMOS and NMOS transistors, including the first PMOS transistor having the p-well, SP, layer, and the first NMOS transistor having the n-well, SN, layer; the deep n-well, DN, structure having the DN layer; the p-type buried, BP, layer (also known as a BP layer, a buried p-type layer, as understood by the skilled person) disposed to mutually isolate the SN layer and the DN layer; the n-type buried, BN, layer (also known as a BN layer, a buried n-type layer, as understood by the skilled person) providing an SN/BN/DN stack; and the set of contacts, including the first contact, electrically coupled to the DN layer via the SN/BN/DN stack. The first pixel structure is known. Each pixel structure of the array thereof may be as described with respect to the first pixel structure.

The HV creates a considerable depletion region (ideally the full thickness of the sensor, easily achieved with backside biased sensors from a low HV) mostly in the p-substrate. When there is a particle hit, charge carriers are generated in the depletion region. Electrons drift to the DN, and holes to the p-substrate. The charge collected by the DN is measured and processed by the readout electronics. The readout electronics typically include analogue and digital circuits. The analogue circuits amplify, filter and digitise the charge collected by the DN. The digital circuits add critical information to the digitised signal, such as a time tag and the address of the pixel.

In one example, the first pixel structure has a width in a range from 25 μm to 1000 μm, preferably in a range from 50 μm to 500 μm and/or wherein the first pixel structure has a length in a range from 25 μm to 1000 μm, preferably in a range from 50 μm to 500 μm. In this way, by decreasing the width and/or the length of the first pixel structure, a resolution of the HV-CMOS sensor may be increased. Since the topside does not include HV contacts, a mutual spacing between adjacent pixel structures may be minimised and/or optimised, without adversely affecting breakdown voltage.

### Backside

The backside comprises the doped p+ layer therein and/or thereon. It should be understood that the doped p+ layer is an outer layer, optionally an outermost layer in the absence of a metallized layer for example, of the p-substrate and hence may be an exposed surface thereof. In other words, the backside may comprise sequentially outwards: the p-substrate, the doped p+ layer and optionally, a metallized layer. The doped p+ layer is used to reduce the Schottky barrier created at a p-substrate/metal interface, for example to create an ohmic contact. It should be understood that the metallized layer may comprise and/or be a metal or a conductive oxide, for example a transparent conductive oxide such as ITO.

In one example, the backside process comprises of optionally thinning to a required thickness, for example 280 μm, and adding a backside p+ implant and optionally metallisation. With regards to the p+ implant, two different approaches in two different wafers of HV-CMOS sensors may be used, by way of example. In the first approach, beamline implantation and rapid thermal annealing at 450° C. are used. In this case, the p+ implant uses boron as the doping species, with an implant energy set to 50 keV and a beam dose of 5·10¹⁴ at/cm². In the second approach, plasma immersion ion implantation and laser annealing are used. Here the doping species is BF₃ plasma with an implant energy set to 2 keV. The reason for investigating two different approaches for the p+ implant is that plasma immersion ion implantation and laser annealing are supposed to be better. With rapid thermal annealing, not all the boron is properly activated. Use of higher temperatures which could improve this may not be desirable, as annealing effects could have a negative impact on the transistors on the topside. Laser annealing benefits over rapid thermal annealing because the temperature can be localised, so the electronics on the topside are much less likely to be affected. The p+ implant is about 50 nm thin in both approaches. The backside metallisation, with titanium and aluminium, has a total thickness of approximately 1 μm. It is defined across all the area of the backside.

In one example, the backside comprises a metallized layer overlaying the doped p+ layer, wherein the HV bias contact is electrically coupled only to the p+ layer via the metallized layer. In this way, homogeneity of the electric field and therefore of the charge collection in the p-substrate is improved since the HV bias voltage is more uniformly applied.

In one example, the metallized layer comprises and/or is a grid (also known as a mesh). In this way, apertures in the grid allow transmission therethrough of electromagnetic radiation.

### HV Bias Contact

The sensor comprises the HV bias contact electrically coupled only to the p+ layer, for backside biasing thereof. It should be understood that the HV-CMOS sensor does not comprise (i.e. does not include; excludes) an HV bias contact electrically coupled to the topside. It should be understood that in use, the HV bias contact is electrically coupled to a power supply, as understood by the skilled person.

In one example, the HV bias contact is directly electrically coupled only to (i.e. directly contacts) the p+ layer. In one example, the HV bias contact is indirectly electrically coupled only to (i.e. indirectly contacts) the p+ layer, for example via a metallised layer.

In one example, the HV bias contact is a single HV bias contact. In one example, the HV bias contact comprises a set of HV bias contacts, including the HV bias contact (i.e. a first HV bias contact).

In one example, the HV bias contact extends over the backside, for example in a range from 25% to 100%, preferably in a range from 50% to 100%, more preferably in a range from 75% to 100%, by area thereof.

In one example, a distance through the p-substrate between the doped p+ layer and the DN layer is in a range from 20 μm to 500 μm, preferably in a range from 25 μm to 300 μm, more preferably in a range from 50 μm to 280 μm. In this way, a through thickness spacing (tending towards a thickness of the p-substrate) between the HV bias contact electrically coupled only to the p+ layer and the array of pixel structures in and/or on the topside of the p-substrate may be increased, maximised and/or optimised, notwithstanding a desire to reduce a thickness of the p-substrate.

### Method of Sensing Charged Particles

The second aspect provides a method of sensing charged particles using a High Voltage Complementary Metal-Oxide-Semiconductor, HV-CMOS, sensor according to the first aspect, the method comprising:
applying a voltage to the set of contacts, including the first contact, electrically coupled to the DN layer via the SN/BN/DN stack of the first pixel structure;
backside biasing the sensor via the HV bias contact electrically coupled only to the p+ layer; and
sensing the charged particles.

In one example, the method comprises irradiating the sensor at a 1 MeV neutron equivalent fluence in a range from 1×10¹⁴ n_{eq} cm⁻² to 1×10¹⁸ n_{eq} cm⁻², preferably in a range from 1×10¹⁵ n_{eq} cm⁻² to 1×10¹⁷ n_{eq} cm⁻², more preferably in a range from 2×10¹⁵ n_{eq} cm⁻² to 5×10¹⁶ n_{eq} cm⁻². In this way, the 1 MeV neutron equivalent fluence is relatively high, compared with 1 MeV neutron equivalent fluence irradiation of conventional HV-CMOS sensors. Nevertheless, the HV-CMOS sensor according to the first aspect is tolerant to such relatively high 1 MeV neutron equivalent fluence since the HV bias may be increased further before onset of breakdown.

In one example, the method comprises irradiating the sensor for a time in a range from 1 year to 10 years, preferably in a range from 3 years to 7 years. In this way, the HV-CMOS sensor according to the first aspect may be exposed for a relatively long time, compared with conventional HV-CMOS sensors.

In one example, backside biasing the sensor via the set of HV bias contacts, including the first HV bias contact, electrically coupled only to the p+ layer comprises backside biasing the sensor via the set of HV bias contacts, including the first HV bias contact, electrically coupled only to the p+ layer at a voltage in a range from 200 V to 950 V, preferably in a range from 300 V to 900 V. In this way, the HV bias voltage may be increased, for example to compensate for radiation damage during a lifetime of the HV-CMOS sensor, to a relatively higher voltage (approximately an order of magnitude greater), thereby maintaining an efficiency and/or a gain thereof, for example throughout an extended lifetime thereof.

### Method of Fabricating a HV-CMOS Sensor

The third aspect provides a method of fabricating a High Voltage Complementary Metal-Oxide-Semiconductor, HV-CMOS, sensor, the method comprising:
obtaining a p-substrate having a topside and a backside;
providing a topside of the p-substrate, comprising forming an array of mutually spaced apart pixel structures, including a first pixel structure, therein and/or thereon, wherein the first pixel structure comprises: a set of PMOS and NMOS transistors, including a first PMOS transistor having an n-well, SN, layer, and a first NMOS transistor having a p-well, SP, layer; a deep n-well, DN, structure having a DN layer; a p-type buried, BP, layer disposed to mutually isolate the SN layer and the DN layer; an n-type buried, BN, layer providing an SN/BN/DN stack; and a set of contacts, including a first contact, electrically coupled to the DN layer via the SN/BN/DN stack; providing a backside of the p-substrate, comprising doping the p-substrate, thereby providing a doped p+ layer therein and/or thereon; and
electrically coupling an HV bias contact only to the p+ layer, for backside biasing thereof.

In one example, providing the backside of the p-substrate comprises optionally thinning to required thickness, optionally plasma etching to remove defects, p+ implantation to provide the doped p+ layer, optionally thermal annealing at low temperature to activate the p+ implantation, and optionally backside metallization to create the set of HV contacts.

### Definitions

Throughout this specification, the term “comprising” or “comprises” means including the component(s) specified but not to the exclusion of the presence of other components. The term “consisting essentially of” or “consists essentially of” means including the components specified but excluding other components except for materials present as impurities, unavoidable materials present as a result of processes used to provide the components, and components added for a purpose other than achieving the technical effect of the invention.

The term “consisting of” or “consists of” means including the components specified but excluding other components.

Whenever appropriate, depending upon the context, the use of the term “comprises” or “comprising” may also be taken to include the meaning “consists essentially of” or “consisting essentially of”, and may also be taken to include the meaning “consists of” or “consisting of”.

The optional features set out herein may be used either individually or in combination with each other where appropriate and particularly in the combinations as set out in the accompanying claims. The optional features for each aspect or exemplary embodiment of the invention, as set out herein are also applicable to all other aspects or exemplary embodiments of the invention, where appropriate. In other words, the skilled person reading this specification should consider the optional features for each aspect or exemplary embodiment of the invention as interchangeable and combinable between different aspects and exemplary embodiments.

### BRIEF DESCRIPTION OF THE DRAWINGS

For a better understanding of the invention, and to show how exemplary embodiments of the same may be brought into effect, reference will be made, by way of example only, to the accompanying diagrammatic Figures, in which:

FIG. 1A schematically depicts a conventional HV-CMOS sensor; FIG. 1B schematically depicts the conventional HV-CMOS sensor, in more detail; and FIG. 1C schematically depicts the conventional HV-CMOS sensor, in more detail;

FIG. 2A schematically depicts a conventional HV-CMOS sensor; FIG. 2B is a colour map of doping concentration of a simulation of the conventional HV-CMOS sensor (red is high n-type, blue is high p-type); FIG. 2C is a graph of simulated leakage current as a function of reverse substrate bias voltage for the conventional HV-CMOS sensor, having a breakdown voltage of about −77 V; FIG. 2D is a pair of colour maps of electron current density of a simulation of the conventional HV-CMOS sensor at a reverse substrate bias voltage of −70 V (before breakdown, above) and at a reverse substrate bias voltage of ˜80 V (after breakdown, below);

FIG. 3A schematically depicts a HV-CMOS sensor according to an exemplary embodiment; FIG. 3B schematically depicts the HV-CMOS sensor, in more detail; and FIG. 3C schematically depicts the HV-CMOS sensor, in more detail;

FIG. 4A schematically depicts \textcircled{1} a conventional HV-CMOS pixel; FIG. 4B schematically depicts \textcircled{2} a conventional HV-CMOS pixel; FIG. 4C schematically depicts \textcircled{3} a HV-CMOS pixel according to an exemplary embodiment; FIG. 4D schematically depicts the conventional HV-CMOS pixel of FIG. 4A (alternative, equivalent depiction); FIG. 4E schematically depicts the conventional HV-CMOS pixel of FIG. 4B (alternative, equivalent depiction); and FIG. 4F schematically depicts the exemplary HV-CMOS pixel of FIG. 4C (alternative, equivalent depiction);

FIG. 5A is a colour map of doping concentration of a simulation of \textcircled{1} the conventional HV-CMOS pixel of FIG. 4A (topside and backside inset, in more detail); FIG. 5B is a colour map of doping concentration of a simulation of \textcircled{2} the conventional HV-CMOS pixel of FIG. 4B (topside and backside inset, in more detail); and FIG. 5C is a colour map of doping concentration of a simulation of \textcircled{3} the HV-CMOS pixel of FIG. 4C (topside and backside inset, in more detail);

FIG. 6 is a graph of simulated leakage current as a function of reverse substrate bias voltage for: \textcircled{1} the conventional HV-CMOS pixel of FIG. 4A; \textcircled{2} the conventional HV-CMOS pixel of FIG. 4B; and \textcircled{3} the HV-CMOS pixel of FIG. 4C;

FIG. 7A schematically depicts a HV-CMOS sensor according to an exemplary embodiment; FIG. 7B schematically depicts the HV-CMOS pixel, in more detail; and FIG. 7C is a graph of measured leakage current as a function of reverse substrate bias voltage for the HV-CMOS;

FIG. 8 schematically depicts a method of sensing charged particles according to an exemplary embodiment;

FIG. 9 schematically depicts a method of fabricating a HV-CMOS sensor according to an exemplary embodiment;

FIG. 10 schematically depicts a HV-CMOS sensor according to an exemplary embodiment. (a) The layout of the UKRI-MPW0 pixel chip. Areas I and II are the two matrices of active pixels; III is the location of the eTCT test structures, and IV, V are the locations of other passive test structures. (b) The cross-section of the UKRI-MPW0 pixel chip with the CR and CTR shown. Also highlighted is a parasitic transistor channel which can form at lower bias voltages [10]; (c) layout views of the four 3×3 passive pixel matrices included in (a) for I-V characteristics and edge-TCT measurements. (d) Cross-section of the chip edge showing a Current Terminating Ring (CTR) and a Clean-up Ring (CR), and the configuration for current-to-voltage characteristics measurements.

FIG. 11 is a graph showing the arbitrary charge collected at varying bias voltages for an unirradiated BL+RTA sample. The top of the sensor sits around 20150 to 20200 μm, there is variation in the position due to oscillations in the movement stages;

FIG. 12 is a graph showing depletion depth into the sensor with reverse bias voltage. With irradiation the depth to which the sensor could deplete was reduced;

FIG. 13 is a graph showing doping concentration of each sample against irradiated fluence. At lower fluences there is a decrease in doping concentration before it increases again;

FIG. 14 shows current-to-voltage characteristics of four unirradiated UKRI-MPW0 samples (two for each backside processing methods);

FIG. 15 shows measurement scheme for studying the parasitic channel between the rings and pixel;

FIG. 16 shows measured pixel current Iₚᵢₓₑₗ for different V_{ring} and high voltages −HV;

FIG. 17 shows current-to-voltage characteristics of two samples irradiated to a neutron fluence of 1×10¹⁴ n_{eq} cm⁻² (measured at room temperature);

FIG. 18 shows discriminator output signals of the continuous-reset and switched-reset pixels in response to a 20 ke⁻ injection signal; and

FIG. 19 shows hit map of matrix I in response to a ⁹⁰Sr source when the chip was biased to −500 V and with a shutter window of 20 s. The first 10 columns are continuous-reset pixels. Columns 11-20 are switched-reset pixels and the rest are modulated-reset pixels.

### DETAILED DESCRIPTION OF THE DRAWINGS

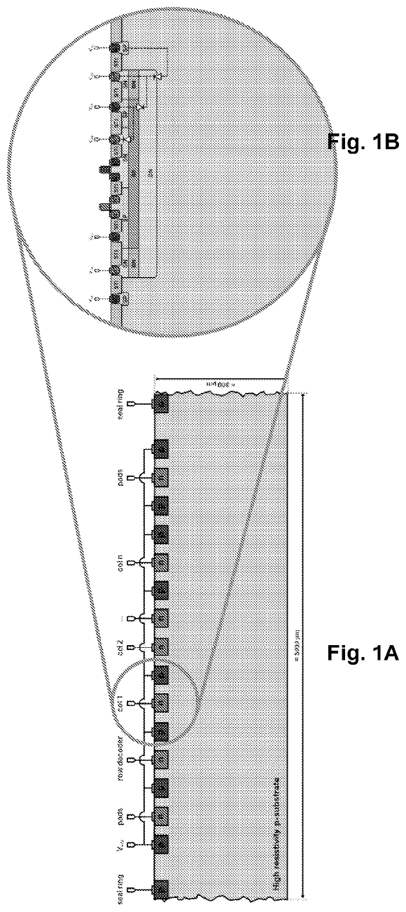

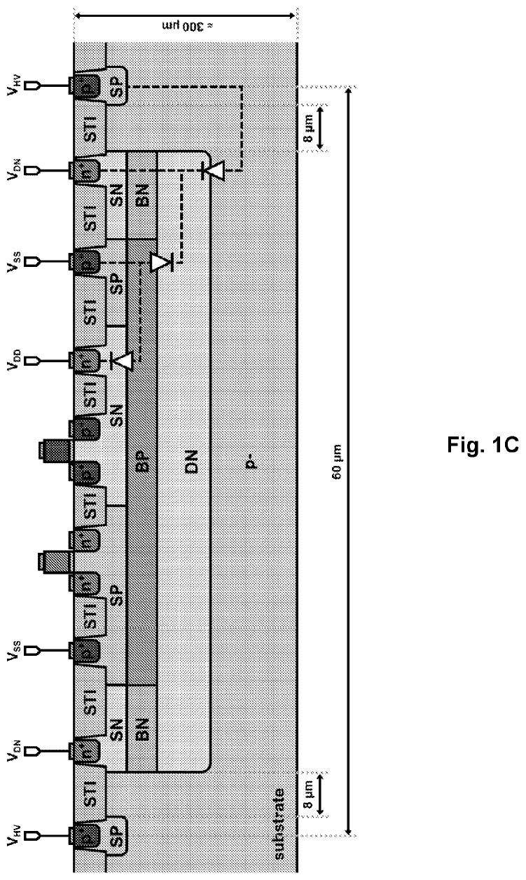

FIG. 1A schematically depicts a conventional HV-CMOS sensor; FIG. 1B schematically depicts the conventional HV-CMOS sensor, in more detail; and FIG. 1C schematically depicts the conventional HV-CMOS sensor, in more detail.

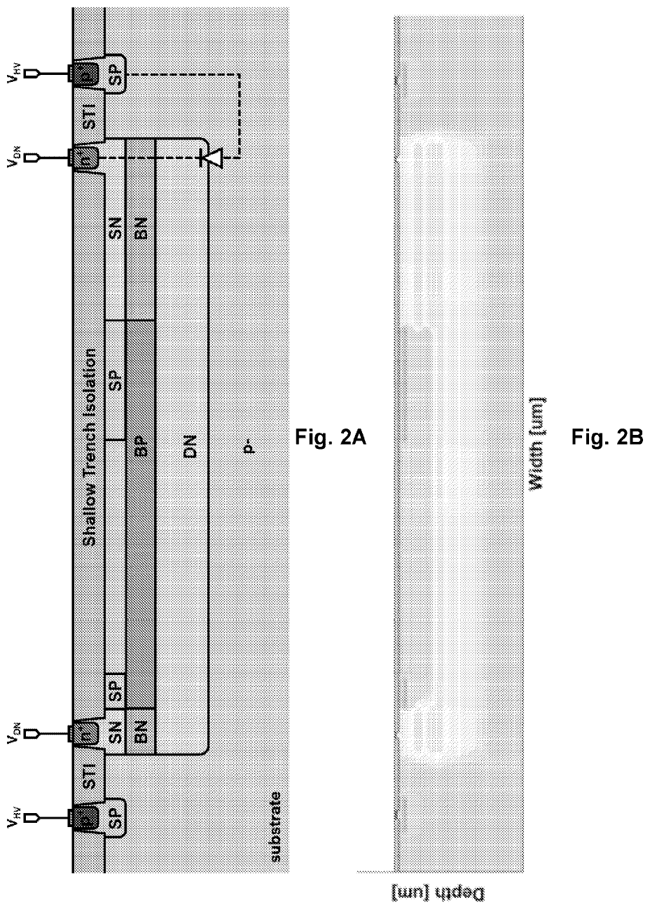

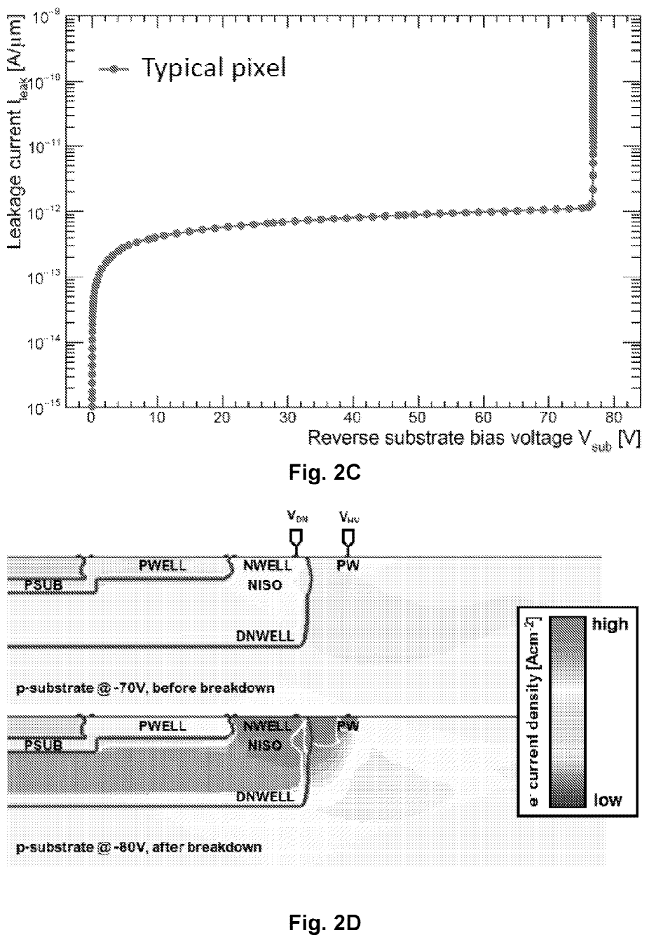

FIG. 2A schematically depicts a conventional HV-CMOS sensor; FIG. 2B is a colour map of electron current density of a simulation of the conventional HV-CMOS sensor; FIG. 1C is a graph of leakage current as a function of reverse substrate bias voltage for the conventional HV-CMOS sensor, having a breakdown voltage of about −77 V; FIG. 2D is a pair of colour maps of electron current density of a simulation of the conventional HV-CMOS sensor at a reverse substrate bias voltage of −70 V (before breakdown, above) and at a reverse substrate bias voltage of −80 V (after breakdown, below).

### Simulations

To recreate backside processing, the Sentaurus Process TCAD tool from Synopsys was used. Then, in order to simulate larger structures, such as individual pixels, the simulated doping profile is imported into Sentaurus Structure Editor (SDE). Finally, reverse I-V characteristics are simulated, and depletion depths extracted and compared with measurements.

### Backside Processing

A 1D region of silicon was defined with a length of 5 μm. This length was used to properly characterise the vertical doping profile while keeping simulation time to a minimum. A simple meshing scheme was employed with 1 nm spacing close to the implant surface, and node spacing increasing to 10 nm at a 1 μm depth. No doping was applied to the silicon substrate.

The p-type implant was introduced into the substrate using MC implantation, with the number of pseudoparticles set to 100000. Boron was used as the doping species, implant energy was set to 50 keV, and a beam dose of 5×10¹⁴ ions cm⁻² was used. The wafer tilt and rotation angles were both set to 0°. An annealing step was then applied to the simulation for 30 seconds at a temperature of 450° C. The width of the 1 D simulation was extended to 0.5 μm and a mesh node spacing of 50 nm in the x direction.

FIG. 3A schematically depicts a HV-CMOS sensor according to an exemplary embodiment; FIG. 3B schematically depicts a HV-CMOS pixel of the HV-CMOS sensor, in more detail; and FIG. 3C schematically depicts the HV-CMOS pixel, in more detail.

The High Voltage Complementary Metal-Oxide-Semiconductor, HV-CMOS, sensor comprises a p-substrate having a topside and a backside;
wherein the topside comprises:
an array of mutually spaced apart pixel structures, including a first pixel structure, therein and/or thereon, wherein the first pixel structure comprises: a set of PMOS and NMOS transistors, including a first PMOS transistor having an n-well, SN, layer, and a first NMOS transistor having a p-well, SP, layer; a deep n-well, DN, structure having a DN layer; a p-type buried, BP, layer disposed to mutually isolate the SN layer and the DN layer; an n-type buried, BN, layer providing a SN/BN/DN stack; and a set of contacts, including a first contact, electrically coupled to the DN layer via the SN/BN/DN stack;
wherein the backside comprises:
a doped p+ layer therein and/or thereon; and
wherein the sensor comprises an HV bias contact electrically coupled only to the p+ layer, for backside biasing thereof.

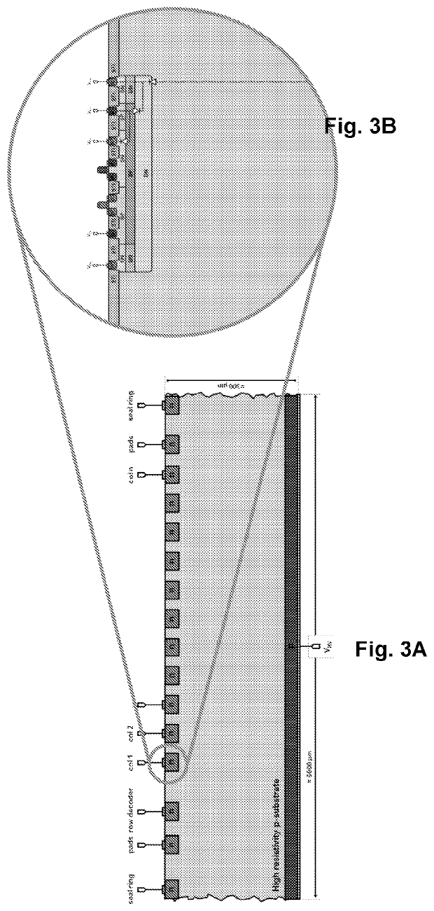

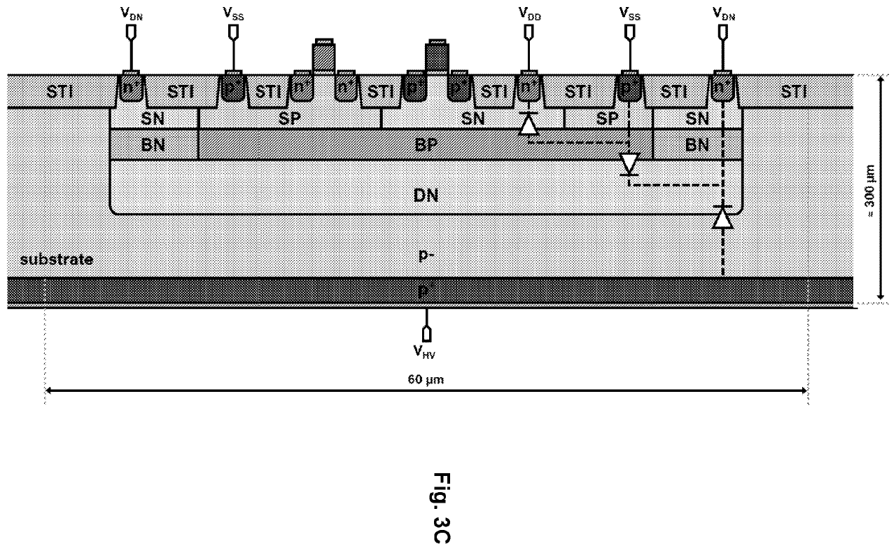

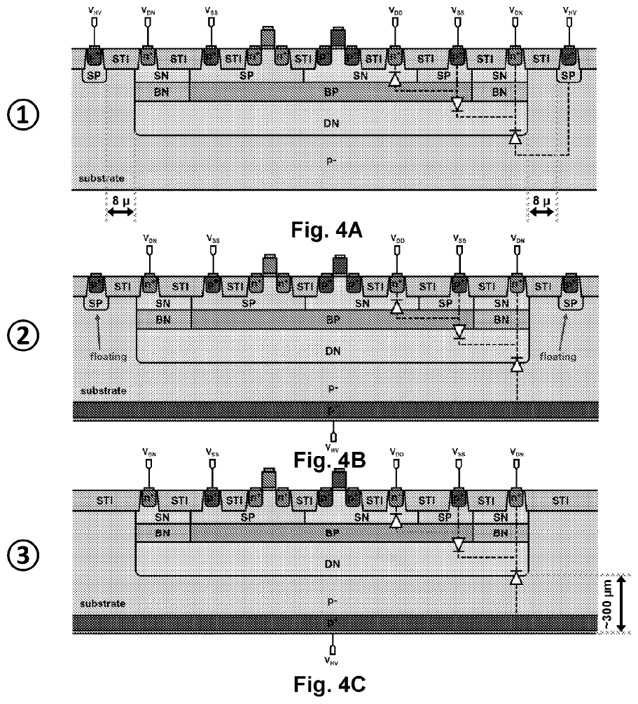

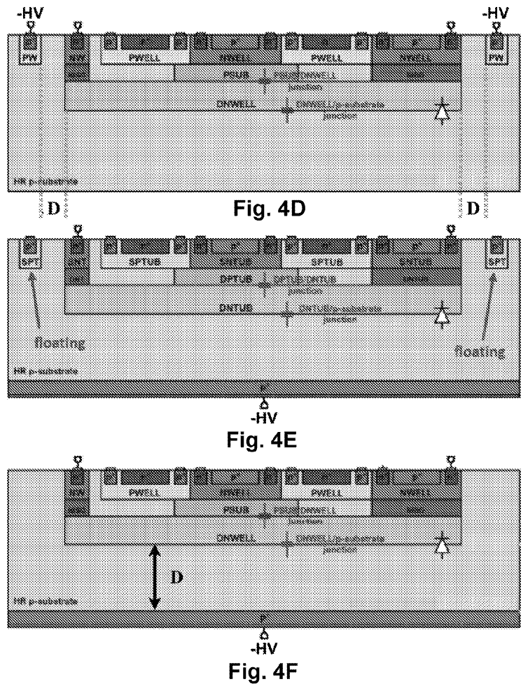

FIG. 4A schematically depicts \textcircled{1} a conventional HV-CMOS pixel; FIG. 4B schematically depicts \textcircled{2} a conventional HV-CMOS pixel; and FIG. 4C schematically depicts \textcircled{3} a HV-CMOS pixel according to an exemplary embodiment.

FIG. 4B shows a pixel device with backside processing, which has been implemented after fabrication by a third party, to enable biasing the substrate from the backside. The topside contacts have been included to enable biasing the substrate from the topside should the backside processing not work as expected. The device uses a p-type substrate, with samples produced with high substrate resistivities.

Each pixel is implemented by means of three deep n-wells (DNs in the diagram) in the p-substrate forming three p-n junctions which are connected in parallel. In the larger matrices, readout electronics are implemented into the central DN, which also acts as isolation from the p-substrate. NMOS logic is implemented into shallow p-wells (SPs) inside the DN and pMOS logic is implemented into shallow n-wells (SN).

The structure studied to demonstrate the efficiency of this method provides two readout channels, one to access the central pixel and the other one to access the outer eight pixels, which are shorted together. The central pixel is the main focus of this study. The SNs are biased to 0 V in all measurements.

### Backside Processing

A wafer with the present pixel device was backside processed and diced. Backside processing included TAIKO thinning to 100 μm using 4000 grade mesh and plasma etching to remove potential defects, p+ implantation, thermal annealing at low temperature to activate the implantation, and backside metallization to create a contact.

After dicing, the edges of the samples were polished with 3 μm grit lapping sheet and 1/10 μm grade diamond paste to remove the defects. Only the edge of the device illuminated with the laser in the measurements was polished however, since after thinning samples became very brittle and polishing a single edge reduced the likelihood of breakages.

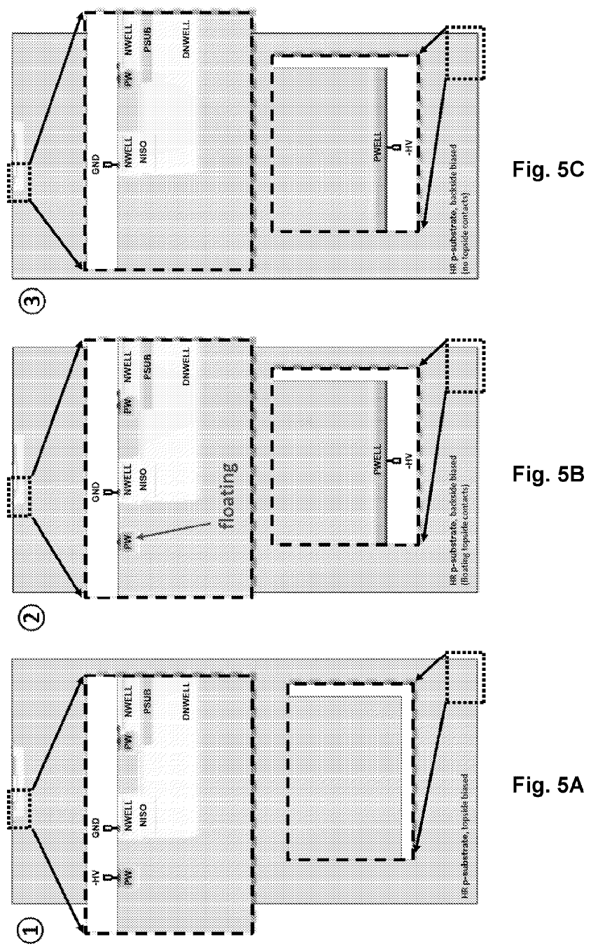

FIG. 5A is a colour map of doping concentration of a simulation of \textcircled{1} the conventional HV-CMOS pixel of FIG. 4A (topside and backside inset, in more detail); FIG. 5B is a colour map of doping concentration of a simulation of \textcircled{2} the conventional HV-CMOS pixel of FIG. 4B (topside and backside inset, in more detail); and FIG. 5C is a colour map of doping concentration of a simulation of \textcircled{3} the HV-CMOS pixel of FIG. 4C (topside and backside inset, in more detail).

FIG. 6 is a graph of simulated leakage current as a function of reverse substrate bias voltage for: \textcircled{1} the conventional HV-CMOS pixel of FIG. 4A; \textcircled{2} the conventional HV-CMOS pixel of FIG. 4B; and \textcircled{3} the HV-CMOS pixel of FIG. 4C.

### Measurements

A Particulars scanning-TCT system was used for the measurements. Using silver conductive paint, samples were glued to a custom PCB, which features a large pad to enable backside biasing. The test structure pads were wire bonded to the PCB in order to process read-out signals. To reduce contributions from noise to the signal and avoid effects of annealing in irradiated samples, PCBs were mounted on a Peltier-cooled stage and kept at −20° C. for the duration of the measurements.

### Current-Voltage

Current-voltage (I-V) measurements were used to determine the reverse breakdown voltages VBD of the samples, and therefore, the safe maximum operating voltages for e-TCT measurements. The pad of the PCB for backside biasing the samples was connected to the negative terminal of a Keithley 2410 source meter and the pad of the central deep n-well was connected to the positive terminal. The supply was ramped to a negative high voltage in 1 V steps, and the current was recorded. Compliance current was set to 10 μA. At this value, the diode was considered to have reached reverse breakdown, and the measurement was stopped.

The leakage current Ileak increases with fluence ϕeq, which is expected due to lattice damage in the bulk. Variations in VBD of the non-irradiated and low fluence samples can be expected due to initial device-to-device variation, but higher fluence samples (3·10¹⁵ n_{eq} cm⁻² and above) were observed to exhibit a softer breakdown, allowing samples irradiated to higher fluences to be biased to higher voltages in e-TCT measurements. Ileak of the non-irradiated sample and sample irradiated to 1·10¹⁴ n_{eq} cm⁻² (at low voltages) was too low to measure accurately with the equipment. The increase in leakage current for the sample irradiated to 1·10¹⁴ cm⁻² is not understood.

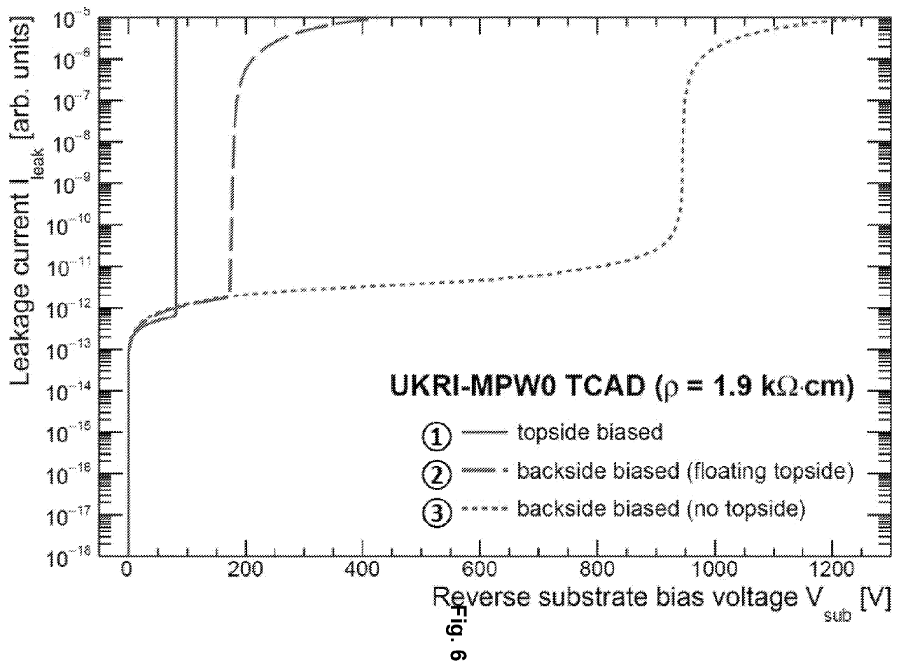

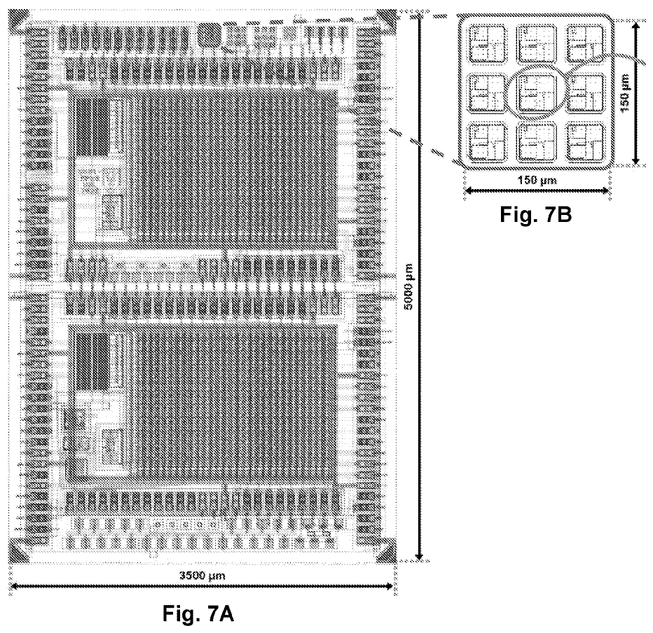

FIG. 7A schematically depicts a HV-CMOS sensor according to an exemplary embodiment; FIG. 7B schematically depicts the HV-CMOS pixel, in more detail; and FIG. 7C is a graph of leakage current as a function of reverse substrate bias voltage for the HV-CMOS.

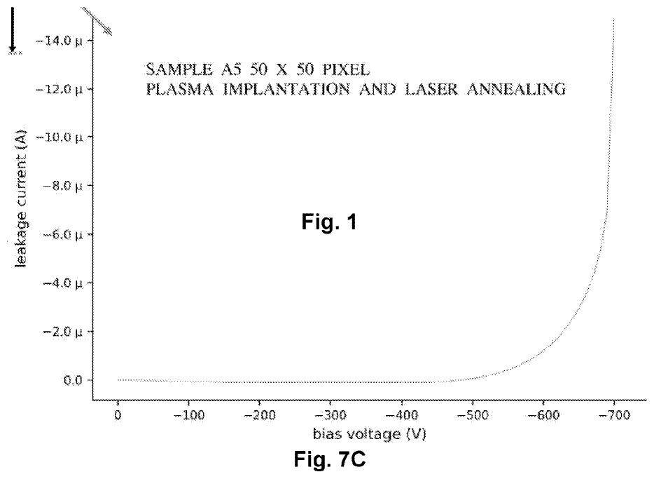

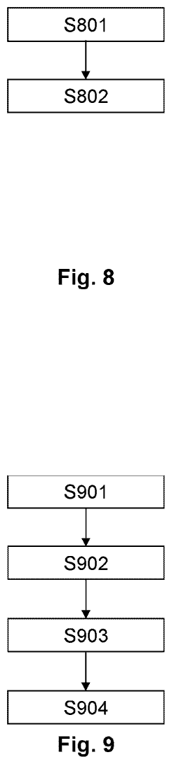

FIG. 8 schematically depicts a method of sensing charged particles according to an exemplary embodiment.

The method is a method of sensing charged particles using a High Voltage Complementary Metal-Oxide-Semiconductor, HV-CMOS, sensor according to the first aspect, the method comprising:
applying a voltage to the set of contacts, including the first contact, electrically coupled to the DN layer via the SN/BN/DN stack of the first pixel structure (S801); and
backside biasing the sensor via the HV bias contact electrically coupled only to the p+ layer; and
sensing the charged particles (S802).

FIG. 9 schematically depicts a method of fabricating a HV-CMOS sensor according to an exemplary embodiment.

The method comprises:
obtaining a p-substrate having a topside and a backside (S901);
providing a topside of the p-substrate, comprising forming an array of mutually spaced apart pixel structures, including a first pixel structure, therein and/or thereon, wherein the first pixel structure comprises: a set of PMOS and NMOS transistors, including a first PMOS transistor having an n-well, SN, layer, and a first NMOS transistor having a p-well, SP, layer; a deep n-well, DN, structure having a DN layer; a p-type buried, BP, layer disposed to mutually isolate the SN layer and the DN layer; an n-type buried, BN, layer providing a SN/BN/DN stack; and a set of contacts, including a first contact, electrically coupled to the DN layer via the SN/BN/DN stack (S902);
providing a backside of the p-substrate, comprising doping the p-substrate, thereby providing a doped p+ layer therein and/or thereon (S903); and
electrically coupling an HV bias contact only to the p+ layer, for backside biasing thereof (S904).

### Experimental Report

This report presents the edge Transient Current Technique (eTCT) measurements of passive test-structures on the UKRI-MPW0 pixel chip, a 280 μm thick proof-of-concept High Voltage-CMOS (HV-CMOS) device designed and fabricated in the LFoundry 150 nm technology node with a nominal substrate resistivity of 1.9 kΩ cm. Samples were irradiated up to 1×10¹⁶ 1 MeV n_{eq} cm⁻² with neutrons to observe the change in depletion depth and effective doping concentration with irradiation. A depletion depth of the sensor was found to be ≈50 μmat≈−400V at 1×10¹⁶ 1 MeV n_{eq} cm⁻². A stable damage introduction rate (g_{c}) was also calculated to be 0.011±0.002 cm⁻¹.

### 1 Introduction

Trackers are an invaluable tool for high-energy physics experiments. Generally placed millimetres from the beam pipe and collision centre, combined with a strong magnet they can determine the mass and charge of an ionising particle passing through the detector [1]. Due to this compact nature the sensing system has to be able to withstand high doses of radiation while also having a fine spatial and temporal resolution able to resolve multiple interactions per collision. Readout of events has to be done at a rate which, in some colliders, can reach the GHz range all while being as thin as possible so as not to disrupt the curved path of the particles [2]. To further fundamental knowledge on physics, experiments are probing higher energies and luminosities. This will mean an increase in the operational parameters of detectors. Silicon sensors are expected to endure fluences exceeding 10¹⁶ 1 MeV n_{eq} cm⁻² as part of the High Luminosity-LHC (HL-LHC), or 10¹⁷ 1 MeV n_{eq} cm⁻² as part of the Future Circular Collider for hadron-hadron collisions (FCC-hh) [3].

High Voltage-CMOS (HV-CMOS) sensors combine a high biasing voltage, for radiation tolerance and fast charge collection by drift, a fine granularity, not limited by expensive bump bonding, and a low material budget, from its integrated circuitry (IC), in a cost effective device as they are produced through an industrial standard manufacturing processes. Other options for silicon trackers do not, currently, offer the same specifications, because of this HV-CMOS is a prime candidate for reaching the requirements of future experiments. A challenge for silicon trackers is the change in doping profile after exposure to Non-Ionising Energy Loss (NIEL). NIEL decreases substrate resistivity through the introduction of acceptor states deep in the silicon, this also changes the breakdown voltage of the sensor and the depletion region around the pixel [4, 5].

This report presents edge Transient Current Technique (eTCT) [6] measurements of a proof-of-concept HV-CMOS sensor designed to increase the radiation tolerance through high biasing voltages.

### 2 Samples and Post-Processing

### 2.1 UKRI-MPW0

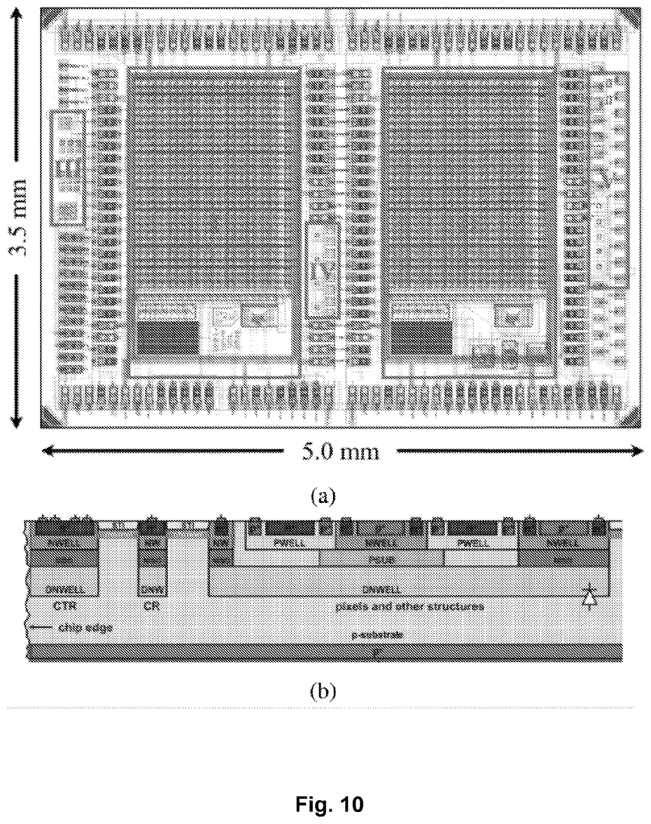

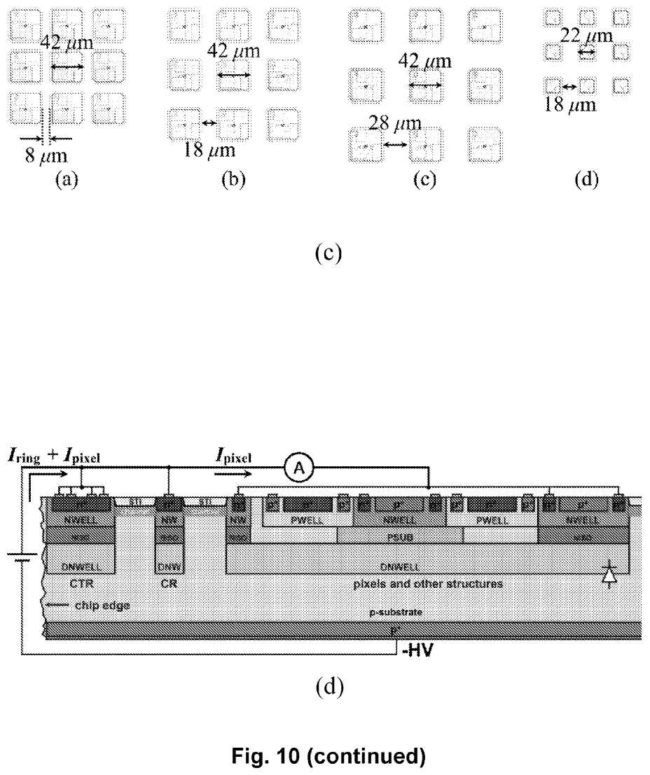

The UKRI-MPW0 (depicted in FIG. 10) is a proof-of-concept HV-CMOS pixel chip crafted using the LFoundry 150 nm technology node. With a nominal substrate resistivity of 1.9 kΩ cm, the sensor has been thinned to 280 μm before being processed for backside biasing. On the chip there are two active matrices of 20×29 pixels with a pixel size 60 μm×60 μm, and three sets of passive test structures for various measurements including passive pixels for eTCT, all of which are highlighted in FIG. 1(a). The eTCT test structures consist of four 3×3 passive pixels with the n-wells from the outer 8 pixels shorted together with the intent to measure the central pixel to replicate the conditions of a wider matrix. This report focuses on the test structure which has the nominal 60 μm×60 μm pixel size.

The chip is designed to increase the breakdown voltage beyond current capabilities of the technology by utilising backside biasing and a total lack of topside p-wells traditionally used for biasing or left floating if a backside biasing scheme is used. The topside p-well was omitted as TCAD simulations identified the area as a low resistivity current path which significantly lowered the breakdown voltage of the sensor. An n-well Cleanup Ring (CR), and an n-well Current Terminating Ring (CTR) was used instead of a conventional set of p-well rings to collect the leakage current from the edge of the chip and acts as a seal ring for the chip (see FIG. 10(b)) [7-9]. The reduced number of rings in this scheme increases the fill factor, but has proved to give a large leakage current (≈4 mA). The high current means the breakdown voltage of the sensor is limited by the current which can pass through the ring before thermal runaway occurs as opposed to the breakdown of the pixel itself. However, the n-well ring structure put in place has led to a high current from the edge of the chip leading to a measured breakdown voltage of ≈−600V [10].

### 2.2 Backside Processing

To add a backside p+ region and metal contact for biasing, two wafers were sent to Ion Beam Services (IBS) for post-processing. Two methods used for backside processing, BeamLine ion implantation with Rapid Thermal Annealing (BL+RTA), and Plasma Ion Implantation with Ultra Violet laser annealing (PIII+UV). BL+RTA is a well known process to the inventors, however it involves heating the entire chip to high temperatures during the annealing process [11, 12].

Whereas, PIII+UV is a more targeted process which better activates the implanted boron and is less likely to damage embedded electronics as it only heats the necessary parts of the chip in order to anneal the implantation damage [13, 14]. BL+RTA is the focus of this report.

### 2.3 Irradiation Campaign

Samples were irradiated with neutrons at the TRIGA reactor at the Jožef Stefan Institute (JSI) in Ljubljana [15]. 2 samples of each backside processing method were irradiated to varying fluences between 1×10¹³ and 1×10¹⁶ 1 MeV n_{eq} cm⁻².

### 3 Measurements

First the chip edge closest to the eTCT test structures was polished to remove scratches left from the dicing process which might impede the laser. 3 μm lapping was used to smooth large scratches from the edge before it was then polished with 1/10 μm grade diamond paste for the finer scratches. The chip was then glued using conducting paint to a metal contact, for backside biasing, on a custom circuit board with the eTCT test structures at the edge of the board. The pads for the test structures were wire-bonded to the board so connectors could be used for reading the signal. The chip and board were placed on a Peltier cooling system inside a scanning-TCT setup provided by Particulars [16]. The chip and board were kept at −20° C. for all measurements.

3.1 eTCT

eTCT measures the depletion region of a sensing diode by way of a pulsed Infrared (IR) laser of wavelength 1064 nm being placed incident to the edge of the chip. The focal point, or beam waist, penetrates into the silicon where it generates electron-hole pairs which drift to the collection electrodes due to the biasing field. By moving the beam waist in all three dimensions inside the silicon and recording the charge collected by the pixel at each location, the sensing region can be mapped. Current induced on the electrodes by the signal was then amplified by a discrete amplifier, and read by an oscilloscope. A10 ns window around the current waveform was integrated to obtain an arbitrary charge collected per laser pulse. As samples were glued and polished by hand variations in pixel position from sample to sample were inevitable. To find the relevant pixel, and focus, a scan in the x and z direction (horizontal and vertical directions in FIG. 1(b) respectively) and a scan in the y and z directions (into the diagram and vertical directions in FIG. 1(b) respectively) were performed, using a knife edge technique. Once done the x and y positions were fixed. The sensor was then biased to −600V with a compliance current in place. The z direction was then scanned over 400 μm in increments of 2 μm before the voltage was decreased and the z direction measured again, until 0V was reached. The voltage was reduced by 25V between −600V and −450V, then a finer step of 10V was used from −450V to 0V. This was done to observe how the depletion region grows with voltage and how neutron irradiation damaged the sensor.

### 4 Results and Analysis

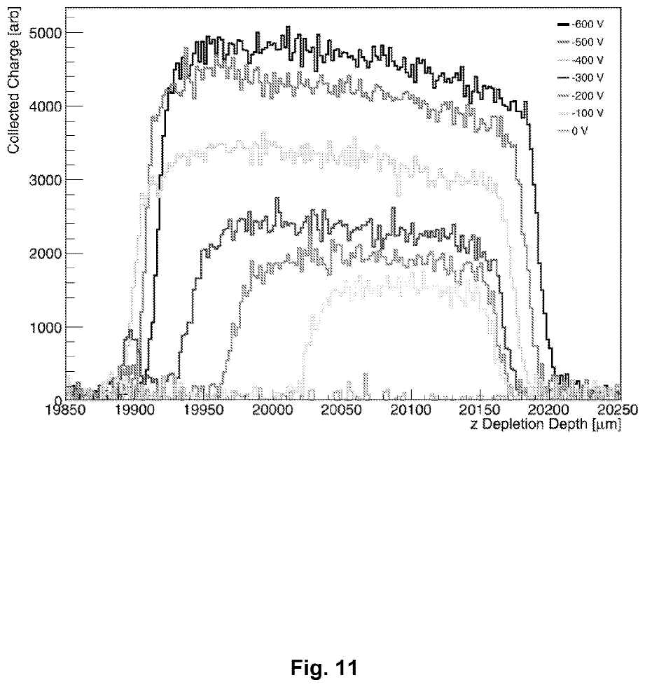

The depletion depth of a sensor was defined as a Full Width Half Maximum (FWHM) for the arbitrary charge collection profile in the z direction. This was done for every voltage measured to establish the depletion regions growth. FIG. 11 shows the charge collected at varying voltages for an unirradiated BL+RTA sample. A secondary peak can be seen around 19900 μm for voltages before full depletion, this is due to backside processing. At higher voltages these peaks merge.

The depletion depth was found by taking the maximum charge collected in the histogram and counting the number of adjacent bins above half this maximum then multiplying by the width of a single bin to find the depletion depth in micrometres. The uncertainty of the depletion depth was calculated using the square root of the number of counted bins multiplied by the bin width. The depletion growth with reverse bias can be fitted to find the effective doping concentration N_{eff,0} through:

$${W}_{D} = {W}_{0} + \sqrt{\frac{2 ϵ}{{qN}_{eff}} {V}_{b ias}} \qquad ( 4.1 )$$

where W_{D} is the depletion depth, W₀ is the depletion depth at 0V, ∈ is the permittivity of silicon, q the charge of an electron, and V_{bias} the reverse bias voltage. Equation (4.1) was fit to the depletion depth with voltage for all measured samples, FIG. 12. The data points were fitted before full depletion or breakdown voltage was reached to accurately represent the growth of the depletion region. At low fluences the depletion depth growth follows equation (4.1) and the sensors are able to reach the full depletion. Full depletion can be seen in FIG. 12 as a discontinuity in between 300V and 400V for the unirradiated and lower fluence samples; this can be attributed to the backside processing. Backside processed samples produce two depletion peaks for the topside n-well pixel, and the backside p+ region as mentioned when discussing FIG. 11. As the voltage increases the depletion region around the topside well grows down into the substrate where the two meet [17]. With further irradiation the depletion depth grows at a slower rate and the discontinuity disappears due to the sensor not being able to fully deplete. At the highest fluence of 1×10¹⁶ 1 MeV n_{eq} cm⁻² a depletion depth of ≈50 μm is achieved at −400 V.

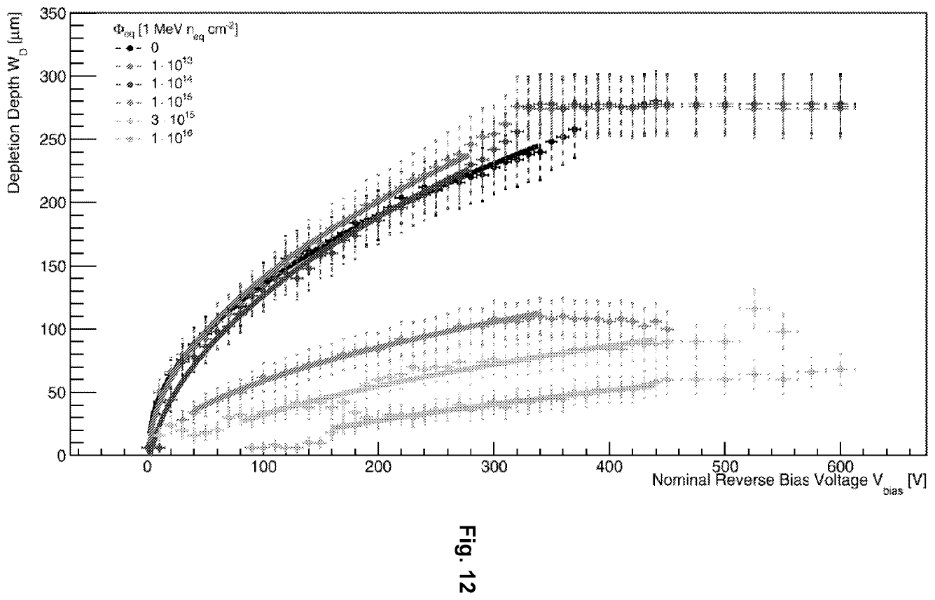

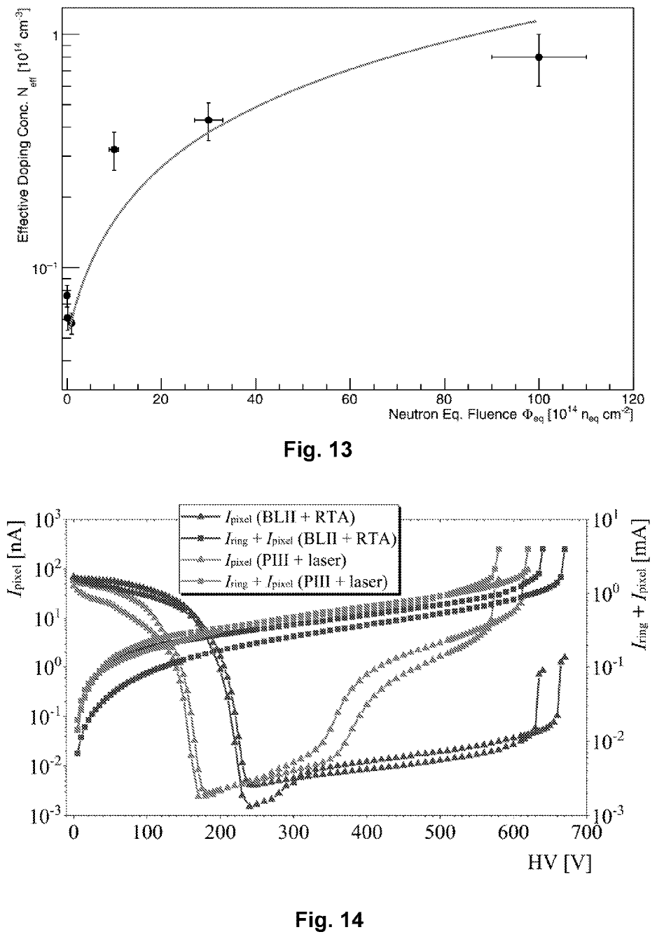

The effective doping profile extracted from the fit was also used to find the resistivity of the chip [18]. The nominal resistivity of the substrate is 1.9 kΩ cm, however the actual resistivity was found to be 1.19±0.14 kΩ cm which is in agreement with measurements of similar sensors crafted in the same technology, process, and nominal resistivity [19, 20]. The effective doping concentration is plotted against the fluence and fitted using:

$${N}_{eff} = {N}_{eff , 0} - {N}_{c} ( 1 - {e}^{- c {ϕ}_{eq}} ) + {g}_{c} {ϕ}_{eq} \qquad ( 4.2 )$$

where N_{eff,0} is the effective doping concentration before irradiation, N_{c} is the concentration of acceptors which have been deactivated, with c being the acceptor deactivation constant, g_{c} is the stable damage introduction rate, and ϕ_{eq} corresponds to the irradiated fluence. Equation (4.2) describes the initial acceptor deactivation and continual increase in effective doping of a silicon semiconductor. FIG. 13 shows a decrease in doping concentration between 0 and 1×10¹⁴ 1 MeV n_{eq} cm⁻², which is consistent with initial acceptor deactivation, before the doping concentration increases again with radiation damage. At higher fluences the linear terms of the equation can be seen to dominate. The fitting parameters from Equation (4.2), shown in Table 1, have large uncertainties, however the data was sufficient to establish the stable damage introduction rate (g_{c}) as 0.011±0.002 cm⁻¹, which was lower than other measurements of chips produced with the same and different technologies, but was in agreement with the literature, as were the other variables of the fit, Table 1 [17, 19, 21, 22].

TABLE 1
Extracted parameter values from equation (4.2) and FIG. 13.

| | | UKRI-MPW0 |
|---|---|---|
| N_{eff0} | [10¹⁴ cm⁻³] | 0.076 ± 0.008 |
| N_{c} | [10¹⁴ cm⁻³] | 0.027 ± 0.010 |
| c | [10⁻¹⁴ cm²] | 9 ± 8 |
| g_{c} | [cm⁻¹] | 0.011 ± 0.002 |

### 5 Conclusion

A proof-of-concept, backside bias only, prototype HV-CMOS pixel chip was irradiated to varying fluences up to 1×1016 1 MeV neq cm−2 and a passive test structure was measured by eTCT between nominal biases of 0V and −600V to observe changes in doping concentration, resistivity, and depletion region growth with NIEL damage. It was shown that at there is a depletion of ≈50 μm at ≈−400V after 1×1016 1 MeV neq cm−2 of irradiation. The decrease in depletion region was also fit. Although there were large uncertainties in the fitting parameters, it was found that the stable damage introduction rate (g_{c}) was 0.011±0.002 cm⁻¹, which is in agreement with literature.

### Experimental Report (Continued)

### HV-CMOS Sensor Biasing Schemes

Three sensor biasing schemes are shown in FIG. 4:
(A and D) The substrate is biased to a high voltage (−HV) via contacts on the topside only, which is the typical biasing scheme in HV-CMOS processes. It is used in AstroPix;
(B and E) The high voltage is applied via backside substrate contacts with topside contacts left floating, which has been tested in LF-Monopix2 and H35DEMO;
(C and F) The high voltage is applied via backside contacts only without any topside contacts.

This novel scheme is used for the first time in UKRI-MPW0.

Technology Computer Aided Design (TCAD) simulations have been conducted to compare these biasing schemes. The simulated current-to-voltage (I-V) characteristics of the three different schemes in FIG. 4 are shown in FIG. 6. The simulation results indicate that backside biasing increases the sensor breakdown voltage V_{BD} when comparing schemes (A and D) and (B and E), and further increases with scheme (C and F). A higher breakdown voltage allows the sensor to be biased to higher biasing voltages. Since the depletion region width W_{d} of the sensing volume is related to the biasing voltage V_{bias} and substrate resistivity ρ_{sub} as W_{d}∝\sqrt{ρ_{sub}·V_{bias}}, a higher biasing voltage is desirable to maintain a wide W_{d} in the sensor before and after irradiation. Therefore, the higher breakdown voltage of the backside-only biasing scheme potentially leads to higher radiation tolerance.

### Chip Design

UKRI-MPW0, as shown in FIG. 10(a), is composed of:
I. A 20×29 pixel matrix with 3 pixel flavours using linear transistors (each pixel has a size of 60 μm×60 μm);
II. A copy of matrix I, which uses two Enclosed Layout Transistors (ELTs) instead of linear transistors inside each pixel for higher radiation tolerance;
III. Test structures for I-V characteristics and edge-Transient Current Technique (edge-TCT) measurements;
IV. Test structures for comparing breakdown voltages of pixels with different corner shapes;
V. Test structures for evaluating ELT characteristics.

UKRI-MPW0 is in the LFoundry 150 nm HV-CMOS process. Two wafers with a high substrate resistivity (1.9 kΩ cm) were backside processed at Ion Beam Services (IBS). They were thinned to 280 μm for stronger electrical field in the depletion region, thus further improving radiation tolerance. Each wafer was then processed using an alternative method:
(1) The p+ on the backside was implanted via Beam-Line Ion Implantation (BLII) with boron and activated by Rapid Thermal Annealing (RTA);
(2) The backside p+was added using Plasma-Immersion Ion Implantation (PIII) and activated by UV laser annealing.

Wafer backside was metallised with titanium and aluminium.

Since there is no topside high-voltage contact in the new biasing scheme, the spacing between different pixel electrodes (i.e., deep n-wells or DNWELLs of pixels) can be shorter than in schemes (a) and (b) without compromising the breakdown voltage. Therefore, pixels in UKRI-MPW0 can
either keep the same electrode size and reduce the inter-electrode spacing, which means smaller pixel size (pixel size is the sum of electrode size and spacing);
or increase the electrode size while reduce the inter-electrode spacing accordingly, which keeps the same pixel size and makes more area for in-pixel electronics.

Four 3×3 matrices of pixels without on-chip readout circuits are included (region Ill in FIG. 10(a)). These pixels have different electrode sizes and inter-spacing as shown in FIG. 10(c). They are aimed at studying the possible effect of pixel geometries on the current-to-voltage characteristics.

Two rings made of N-type layers are placed in the P-type substrate around the chip periphery as shown in FIG. 10(d):
1. A Current Terminating Ring (CTR) that serves not only as a ring that collects the majority of the leakage current caused by the edge damage from dicing, but also as a seal ring (absorbing mechanical dicing stress and as barrier to contamination introduced during sawing process);
2. A Clean-up Ring (CR) that prevents any further diffusion of the edge current into the sensitive volume.

### Current-to-Voltage Characteristics Measurements

FIG. 10(d) also illustrates the configuration for I-V characteristics measurements. A high voltage (−HV) is applied to the backside of the chip using a Source Measure Unit (SMU). The leakage current flowing into the pixel (Iₚᵢₓₑₗ) is measured by a high-precision picoammeter. The SMU measures the combined current into the rings and pixel (I_{ring}+Iₚᵢₓₑₗ) which can be approximated as Iₚᵢₓₑₗ since Iₚᵢₓₑₗ>>I_{ring} (I_{ring}+Iₚᵢₓₑₗ≈Iₚᵢₓₑₗ).

Initial measurements probed the central pixel of matrix (b) shown in FIG. 10(c) which has the same geometry as the pixels in the two active pixel matrices. FIG. 14 shows the measured current-to-voltage characteristics of four unirradiated samples, two of which are from the wafer backside processed with BLII+RTA and the other two are with PIII and UV laser.

Both samples have breakdown voltages higher than 600 V. The pixel leakage currents Iₚᵢₓₑₗ have values of tens of nA when the bias voltage is below 100 V and decrease until the biasing voltage reaches ˜200 V. Beyond this voltage, the pixel leakage currents gradually increase as in typical silicon sensors reaching ˜10⁻² nA before breakdown. This leakage value matches the literature. A large amount of leakage current (˜mA) is collected by the peripheral rings, which is caused by the damage on the chip edges.

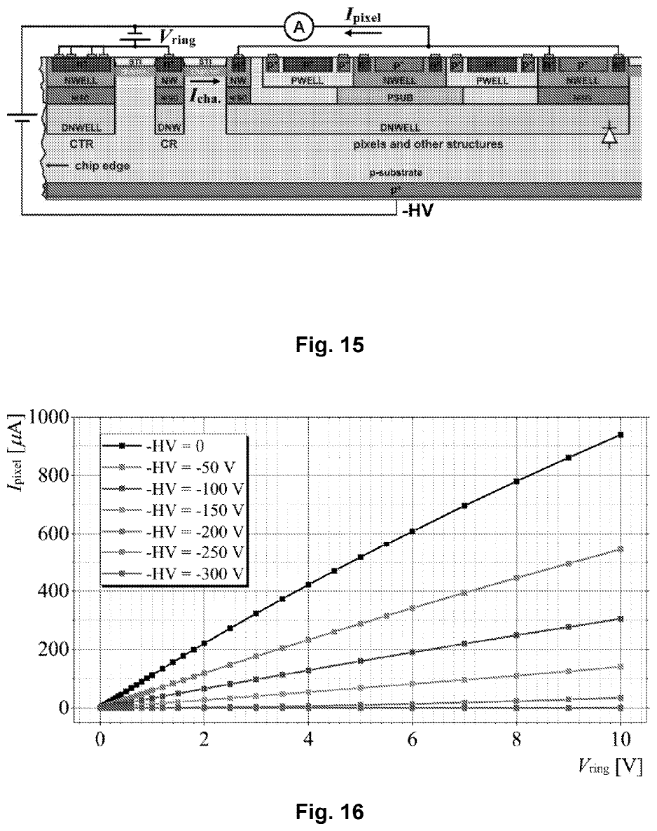

It is believed that the high pixel leakage current at low bias voltages is because an inversion channel exists beneath the Shallow Trench Isolation (STI) layer between rings and pixels as shown in FIG. 10(d). Such a channel provides a path for the high leakage current before the turning point at ˜200 V. A measurement to prove the existence of such a parasitic channel has been made following the scheme shown in FIG. 15. The rings are biased to a common voltage V_{ring} and the pixel current Iₚᵢₓₑₗ is measured for different V_{ring} and high voltages −HV.

FIG. 16 shows the measured result. The pixel current Iₚᵢₓₑₗ increases linearly with V_{ring}, which is the voltage difference between the rings and pixel, and decreases with the high bias voltage −HV. This result confirms the existence of the proposed current path between the rings and pixel. The channel is cut off when HV is higher than 200 V and the pixel leakage current Iₚᵢₓₑₗ is dominated by the reverse diode current. Such a behaviour is similar to a transistor working in its triode region (higher −HV increases its threshold voltage due to body effect).

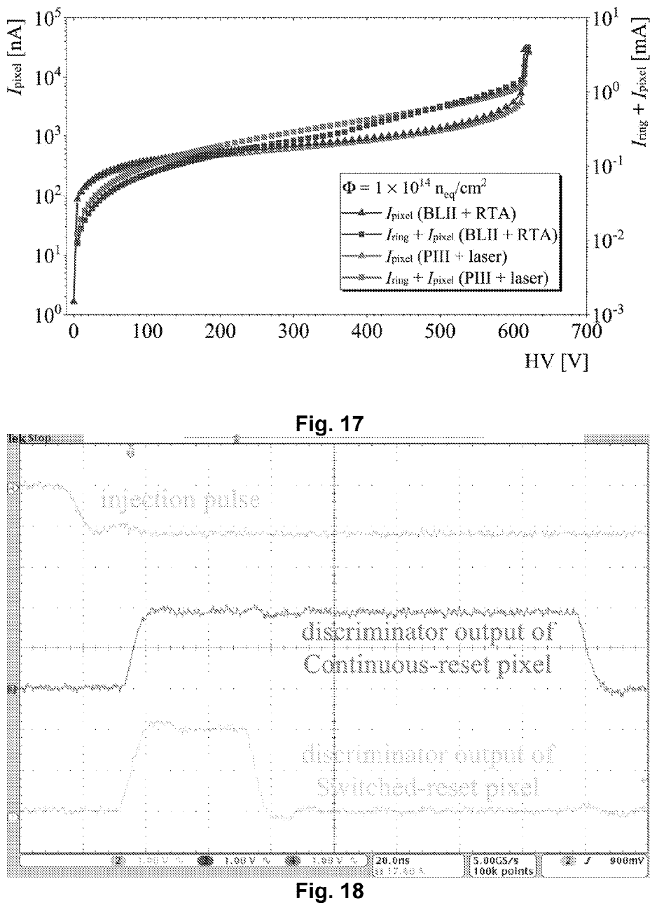

FIG. 17 shows the current-to-voltage characteristics of two samples that have been irradiated with neutrons to a fluence of 1×10¹⁴ n_{eq} cm⁻². The breakdown voltages stay above 600 V and the pixel leakage current Iₚᵢₓₑₗ increases by four orders of magnitude after irradiation. However, at low bias voltages (V_{bias}<5 V) decreases, which indicates the neutron irradiation cuts off the parasitic channel between the rings and pixel.

### Pixel Matrix Measurements

Both pixel matrices I and II contain three different pixel flavours: (1) continuous-reset pixel, (2) switched-reset pixel and (3) modulated-reset pixel. Pixel flavours (1) and (2) have been implemented and tested in a previous prototype RD50-MPW2. Their design and evaluation details can be found in [8], [9]. Pixel flavour (3), which modulates the reset speed based on its input charge, will be published elsewhere. The readout electronics inside each pixel include an injection circuit for calibration and a discriminator. Preliminary measurements have shown pixel matrix I responds to injection pulses and radioactive sources. FIG. 18 shows the response of pixel flavours (1) and (2) to an injection pulse that corresponds to a charge signal of 20 ke⁻. Their discriminator outputs show these two pixel flavours finish processing the 20 ke⁻ signal within 140 ns and 40 ns, respectively. These values agree with those measured with RD50-MPW2.

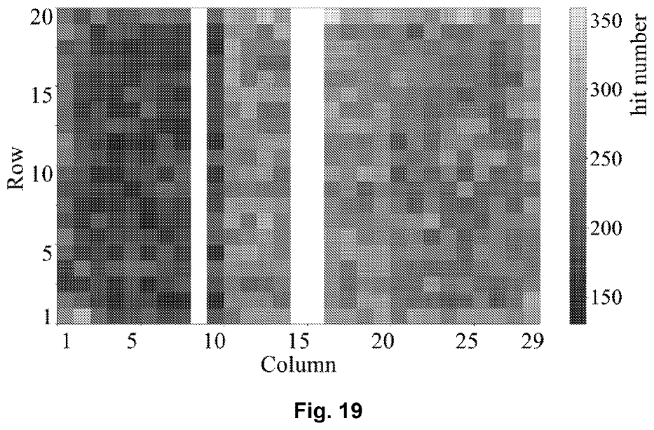

FIG. 19 shows the hit map of matrix I when the chip was exposed to a ⁹⁰Sr source for 20 s and biased to 500 V. Columns 11 to 20, which are switched-reset pixels, record more hits than the others. That is because this pixel flavour has a greater gain as already seen in RD50-MPW2 [9]. Columns 9, 15 and 16 record no hits is due to an issue on the readout board.

### 6 REFERENCES

[1] A. Belyaev and D. Ross, Particle detectors The Basics of Nuclear and Particle Physics, Springer International Publishing, Cham (2021), pp 221-230.
[2] J. Vossebeld, The ATLAS inner tracker for the LHC and plans for an SLHC tracker upgrade, Nucl. Instrum. Meth. A 566 (2006) 178.
[3] E. Vilella, Time resolution and radiation tolerance of depleted CMOS sensors, Proceedings of the 27th International Workshop on Vertex Detectors (VERTEX2018), Vol. 348 (2018).
[4] F. Hönniger, Radiation damage in silicon. Defect analysis and detector properties, Ph.D. Thesis, The Deutsches Elektronen-Synchrotron (2008).
[5] G. Lindstrǒm, Radiation damage in silicon detectors, Nucl. Instrum. Meth. A 512 (2003) 30.
[6] G. Kramberger et al., Investigation of irradiated silicon detectors by edge-TCT, IEEE Trans. Nucl. Sci. 57 (2010) 2294.
[7] E. Noschis, V. Eremin and G. Ruggiero, Simulations of planar edgeless silicon detectors with a current terminating structure, Nucl. Instrum. Meth. A 574 (2007) 420.
[8] E. Noschis et al., Final size planar edgeless silicon detectors for the TOTEM experiment, Nucl. Instrum. Meth. A 563 (2006) 41.
[9] G. Ruggiero et al., Planar edgeless silicon detectors for the TOTEM experiment, IEEE Trans. Nucl. Sci. 52 (2005) 1899.
[10] C. Zhang, M. Franks, J. Hammerich, N. Karim, S. Powell and E. Vilella, Design and evaluation of UKRI-MPW0: an HV-CMOS prototype for high radiation tolerance, Nucl. Instrum. Meth. A 1040 (2022) 167214.
[11] M. L. Franks, Design and characterisation of High-Voltage CMOS (HV-CMOS) detectors for particle physics experiments, Ph. D. Thesis (2022).
[12] V. Danchenko, E. G. Stassinopoulos, P. H. Fang and S. S. Brashears, Activation energies of thermal annealing of radiation-induced damage in N- and P-channels of CMOS integrated circuits, IEEE Trans. Nucl. Sci. 27 (1980) 1658.
[13] E. C. Jones, B. P. Linder and N. W. Cheung, Plasma immersion ion implantation for electronic materials, Jpn. J. Appl. Phys. 35 (1996) 1027.
[14] R. Paetzel, J. Brune, F. Simon, L. Herbst, M. Machida and J. Shida, Activation of silicon wafer by excimer laser, 2010 18th International Conference on Advanced Thermal Processing of Semiconductors, RTP (2010), pp. 98-102.
[15] L. Snoj, G. \hat{ } Zerovnik and A. Trkov, Computational analysis of irradiation facilities at the JSI TRIGA reactor, Appl. Radiat. Isot. 70 (2012) 483.
[16] Particulars advanced measurement systems, https://particulars.si/, Accessed: 30, May 2022.
[17] M. Franks et al., E-TCT characterization of a thinned, backside biased, irradiated HV-CMOS pixel test structure, Nucl. Instrum. Meth. A 991 (2021) 164949.
[18] Resistivity calculator, https://pvlighthouse.com.au/resistivity, Accessed: 16, Sep. 2022.
[19] I. Mandi'c et al., Study of neutron irradiation effects in depleted CMOS detector structures, 2022 JINST 17 P03030.
[20] R. Marco Hernández, Latest depleted CMOS sensor developments in the CERN RD50 collaboration, Proceedings of the 29th International Workshop on Vertex Detectors (VERTEX2020), (2021), p.010008.
[21] I. Mandi'c et al., Neutron irradiation test of depleted CMOS pixel detector prototypes, 2017 JINST 12 P02021.
[22] V. Cindro et al., Radiation damage in p-type silicon irradiated with neutrons and protons, Nucl. Instrum. Meth. A 599 (2009) 60.

### Notes

Although a preferred embodiment has been shown and described, it will be appreciated by those skilled in the art that various changes and modifications might be made without departing from the scope of the invention, as defined in the appended claims and as described above.

At least some of the example embodiments described herein may be constructed, partially or wholly, using dedicated special-purpose hardware. Terms such as ‘component’, ‘module’ or ‘unit’ used herein may include, but are not limited to, a hardware device, such as circuitry in the form of discrete or integrated components, a Field Programmable Gate Array (FPGA) or Application Specific Integrated Circuit (ASIC), which performs certain tasks or provides the associated functionality. In some embodiments, the described elements may be configured to reside on a tangible, persistent, addressable storage medium and may be configured to execute on one or more processors. These functional elements may in some embodiments include, by way of example, components, such as software components, object-oriented software components, class components and task components, processes, functions, attributes, procedures, subroutines, segments of program code, drivers, firmware, microcode, circuitry, data, databases, data structures, tables, arrays, and variables. Although the example embodiments have been described with reference to the components, modules and units discussed herein, such functional elements may be combined into fewer elements or separated into additional elements. Various combinations of optional features have been described herein, and it will be appreciated that described features may be combined in any suitable combination. In particular, the features of any one example embodiment may be combined with features of any other embodiment, as appropriate, except where such combinations are mutually exclusive. Throughout this specification, the term “comprising” or “comprises” means including the component(s) specified but not to the exclusion of the presence of others.

Attention is directed to all papers and documents which are filed concurrently with or previous to this specification in connection with this application and which are open to public inspection with this specification, and the contents of all such papers and documents are incorporated herein by reference.

All of the features disclosed in this specification (including any accompanying claims, abstract and drawings), and/or all of the steps of any method or process so disclosed, may be combined in any combination, except combinations where at least some of such features and/or steps are mutually exclusive.

Each feature disclosed in this specification (including any accompanying claims, abstract and drawings) may be replaced by alternative features serving the same, equivalent or similar purpose, unless expressly stated otherwise. Thus, unless expressly stated otherwise, each feature disclosed is one example only of a generic series of equivalent or similar features.

The invention is not restricted to the details of the foregoing embodiment(s). The invention extends to any novel one, or any novel combination, of the features disclosed in this specification (including any accompanying claims, abstract and drawings), or to any novel one, or any novel combination, of the steps of any method or process so disclosed.

1. A High Voltage Complementary Metal-Oxide-Semiconductor (HV-CMOS) sensor comprising:
a p-substrate having:
a topside, and
a backside;
wherein the topside comprises:
an array of mutually spaced apart pixel structures, including;
a first pixel structure, therein and/or thereon, wherein the first pixel structure comprises:
a set of PMOS and NMOS transistors, including:
a first PMOS transistor having an n-well (SN) layer, and
a first NMOS transistor having:
a p-well (SP) layer;
a deep n-well (DN) structure having a DN layer;
a p-type buried (BP) layer disposed to mutually isolate the SN layer and the DN layer;
an n-type buried (BN) layer providing a SN/BN/DN stack; and
a set of contacts, including a first contact, electrically coupled to the DN layer via the SN/BN/DN stack;
wherein the backside comprises:
a doped p+ layer therein and/or thereon; and
wherein the sensor comprises an HV bias contact electrically coupled only to the p+ layer, for backside biasing thereof.

2. The sensor according to claim 1, wherein a distance through the p-substrate between the doped p+ layer and the DN layer is in a range from 20 μm to 500 μm.

3. The sensor according to claim 1, wherein the array of mutually spaced apart pixel structures includes a second pixel structure and wherein the respective first contacts of the first pixel structure and the second pixel structure are mutually spaced apart by a spacing in a range from 1 μm to 20 μm.

4. The sensor according to claim 1, wherein the array of mutually spaced apart pixel structures includes N mutually spaced apart pixel structures, wherein N is a natural number greater than 2.

5. The sensor according to claim 1, wherein the p-substrate has a thickness in a range from 25 μm to 500 μm.

6. The sensor according to claim 1, wherein the backside comprises a metallized layer overlaying the doped p+ layer, wherein the set of HV bias contacts, including the first HV bias contact, is electrically coupled only to the p+ layer via the metallized layer.

7. The sensor according to claim 6, wherein the metallized layer comprises and/or is a grid.

8. The sensor according to claim 1, wherein the first pixel structure has a width in a range from 25 μm to 1000 μm, and/or wherein the first pixel structure has a length in a range from 25 μm to 1000 μm.

9. The sensor according to claim 1, wherein the HV bias contact extends over the backside, for example in a range from 25% to 100%.

10. The sensor according to claim 1, wherein the HV bias contact is a single HV bias contact.

11. A method of sensing charged particles using a High Voltage Complementary Metal-Oxide-Semiconductor (HV-CMOS) sensor according to claim 1, the method comprising:
applying a voltage to the set of contacts, including the first contact, electrically coupled to the DN layer via the SN/BN/DN stack of the first pixel structure;
backside biasing the sensor via the HV bias contact electrically coupled only to the p+ layer; and
sensing the charged particles.

12. The method according to claim 11, comprising irradiating the sensor at a 1 MeV neutron equivalent fluence in a range from 1×10¹⁴ n_{eq} cm⁻² to 1×10¹⁸ n_{eq} cm⁻².

13. The method according to claim 12, comprising irradiating the sensor for a time in a range from 1 year to 10 years.

14. The method according to claim 11, wherein backside biasing the sensor via the HV bias contact electrically coupled only to the p+ layer comprises:
backside biasing the sensor via the set of HV bias contacts, including the first HV bias contact, electrically coupled only to the p+ layer at a voltage in a range from 200 V to 950 V.

15. A method of fabricating a High Voltage Complementary Metal-Oxide-Semiconductor (HV-CMOS) sensor, the method comprising:
obtaining a p-substrate having a topside and a backside;
providing a topside of the p-substrate, comprising:
forming an array of mutually spaced apart pixel structures, including a first pixel structure, therein and/or thereon,
wherein the first pixel structure comprises:
a set of PMOS and NMOS transistors, including;
a first PMOS transistor having an n-well (SN) layer, and
a first NMOS transistor having;
a p-well (SP) layer;
a deep n-well (DN) structure having a DN layer;
a p-type buried (BP) layer disposed to mutually isolate the SN layer and the DN layer;
an n-type buried (BN) layer providing a SN/BN/DN stack; and
a set of contacts, including a first contact, electrically coupled to the DN layer via the SN/BN/DN stack;
providing a backside of the p-substrate, comprising doping the p-substrate, thereby providing a doped p+ layer therein and/or thereon; and
electrically coupling an HV bias contact only to the p+ layer, for backside biasing thereof.
